(19) United States
(12) Patent Application Publication
(10) Pub. No.: US 2005/0248365 A1
(43) Pub. Date: Nov. 10, 2005

(54) Distributive computing subsystem of generic IC parts

(76) Inventor: Augustine W. Chang, San Jose, CA (US)

Correspondence Address: SAWYER LAW GROUP LLP, P.O. Box 51418, Palo Alto, CA, 94303, US

(21) Appl. No.: 10/841,934

(22) Filed: May 7, 2004

(51) Int. Cl. H03K 19/177

(52) U.S. Cl. 326/39

(57) ABSTRACT

A PCB subsystem of IC parts is proposed. The PCB assembly contains single or plural of chips, each contains Giga Byte storage and 10 k gate equivalent Schottky CMOS (SCMOS) based field programmable gate arrays (SFPGA). The process technology combines CMOS transistors, EEPROM transistors, and low barrier Schottky diodes. The circuit architecture mixes both hardwired and SFPGA functional units. System interface architecture is based on simple low speed host interface, medium speed local peripheral bus, and high-speed on-chip bus. 1.2V supply low power, high capacity, and high flexibility IC product applications are supported. Efficient system integrations prescribe chip implementations with a distributive computing power running with GHz, 100 MHz, and 10 MHz clock rates at various interfaces. Universal chip and OS supports high bandwidth data access, transport, and storage operations with re-configurable circuit units and special nets.

### RELATED APPLICATIONS

The present invention is related to copending U.S. patent application entitled “3D Flash EEPROM Cell and the Methods of Implementing the Same”, Ser. No. 10/800,257, filed on Mar. 11, 2004, and assigned to the assignee of the present invention; and copending U.S. patent application entitled “Variable Threshold Transistor for the Schottky FPGA and Multilevel Storage Cell Flash Arrays”, Ser. No. 10/817,201, filed on Apr. 2, 2004, and assigned to the assignee of the present invention which is related to copending U.S. patent application entitled “SCL Type FPGA with Multi-Threshold Transistors and Method for Forming Same”, Ser. No. ______ (3070P) filed on Apr. 19, 2004, and assigned to the assignee of the present invention, all of which are incorporated by reference herein.

### FIELD OF THE INVENTION

The present invention relates generally to integrated circuits and more particularly to a system and method for a distributive computing subsystem.

### BACKGROUND OF THE INVENTION

Standalone Flash and RAM Memory, and FPGA Parts

The electrical erasable and programmable EEPROM memory devices have become more widely used in the last decade. The technological advances and broad product applications have made EEPROM memory devices the most viable candidate for implementing SOC level component integrations.

On the process and device technology side, the general practice of memories has been focused on the miniaturization of the physical size of the storage bit, scaling down the cell operating voltages and currents and therefore lowering power consumption. Thereby implementing multilevel signal storages per physical cell area can be implemented. In addition, chip apparatus can be built to manage per bit, byte, large and partial arrays, resource sharing schemes. The ultimate goal is to achieve highest level of system integration with mixed analog and logic circuits in a common chip and therefore improve IC devices with performance, reliability, system efficiency and capacity etc.

Flash memory is a good choice for information storage devices based upon their increasing capacity. The names of “Flash memory and logic device” is adopted based upon the device's fast operation and its use in large arrays. The Flash devices are closely related to the Flash technology. The density, power, and speed capability of Flash arrays exceed what is offered by rotating disks, so the semiconductor EEPROM is replacing the mechanical disk medium in many applications. The Flash memory can also replace DRAM/SRAM for certain applications if the speed/performance requirements are met. Flash memory is nonvolatile and has high density per cell for information storage.

The EEPROM device may be applicable as ideal memory device; both as standalone memory/logic part and as part of an embedded storage/logic unit in an ASIC. The Flash device has several attractive features such as compactness, low power and high speed. A Flash device could replace conventional mechanical and optical disks, controller and microprocessors for network and communications. There is an interest to extend the use of the Flash devices in printed circuit board (PCB) assemblies. However, conventional PCB subsystem assemblies still use standalone logic chips, memory chips, and discrete components interconnecting them with the PCB wiring. It is desirable for a small system such as SD card, stick card, pen drives, PDA, mobile phone to merge the memory capacity, processing power, and even some analog functions in a universal IC. This will be advantageous in both the space and cost savings, and to optimize performance.

There are numerous prior art methods and systems in Flash technology which has been utilized for information storage. The Flash transistor has been successfully developed as either a single bit or a dual bit system storage circuit element. However, typically the Flash transistor is not utilized as logic circuit element.

Field Programmable Logic Devices represented by PLA solutions utilizing Flash devices are well known. The field programmable ICs either reconfigure prime term logic arrays or functional units with on-chip wiring switches and tracks. However, these devices are not utilized to make functional units by directly programming the threshold of the switch transistor and in configuring a basic logic circuit unit. A typical FPGA contains standalone CMOS-TTL implementations with device capacity in the range of a couple hundred gates to about 10 k gates. The basic building blocks contain I/O and logic elements for the latch and the TTL hard and soft macros, RAM arrays, wiring switches and tracks. The most advanced FPGA uses 1.8V supply. The device is highly popular for it flexibility and supported software package. It is difficult to merge a Flash array with the CMOS-TTL logic circuit for the process and circuit compatibility issues, and there is no business advantage to merge these technologies for either the manufacturers of FPGA or the manufacturers of Memory standard parts.

In conventional integrated circuits billions of transistors are successfully found therein. However, many parts that perform different functions are still difficult to integrate. One of the most obvious reasons for this difficulty is the process compatibility issue. It is difficult to merge present technologies because of different process cost objectives for volume parts such as memory and logic units. Memory commodity parts are remarkably cost sensitive and even a minor complication would cost more to the standardized parts. As long as the standardized parts are selling in high volume, there is a barrier for any newly emerged parts or approaches to begin. Usually a tremendous breakthrough in speed, density, power, or capacity is required to make this change. In addition typically reliability-availability-serviceability (RAS) must be of a high quality for such a breakthrough.

Nevertheless, an opportunity to merge the FPGA and Flash technology is desired. By adding the computing power with the densest logic circuit to the densest storage devices, a universal part is provided, and great design flexibility is added to device capacity and performance options. Furthermore, logic circuits may be augmented to contain analog function and multi-valued logic, and still perform at low power.

By implementing such a system and method most of the volume PCB subassembly products in the display, memory, and disk areas can be benefit. This subsystem may support small and large machines for data access, transport and storage purposes.

Accordingly, what is needed is a system and method for addressing the need for such devices. The present invention addresses such a need.

### SUMMARY OF THE INVENTION

A printed circuit board (PCB) subsystem of IC parts is disclosed. The PCB assembly contains single or plural of chips, each contains Giga Byte storage and 10 k gate equivalent Schottky CMOS (SCMOS) based field programmable gate arrays (SFPGA). The process technology combines CMOS transistors, EEPROM transistors, and low barrier Schottky diodes. The circuit architecture mixes both hardwired and SCL type FPGA (SFPGA) functional units. The system component interface architecture is based on the combination of using low power, a low speed host interface (˜20 MHz), a medium speed local peripheral bus (˜500 MHz), and high-speed (˜3 GHz) on-chip busses.

For example, 1.2V supply low power, high capacity, and high flexibility IC product applications are supported. Efficient system integrations prescribe chip implementations with a distributive computing power running with GHz, 100 MHz, and 10 MHz clock rates at various interfaces. Mixed serial universal chip (UIC) and OS supports high bandwidth data access, transport, and storage operations with re-configurable software/hardware including the analog logic memory (ALM) circuit units and special nets.

### BRIEF DESCRIPTION OF THE DRAWINGS

FIG. 1A shows a prior art PCB assembly system that includes a host processor uP chip, memory module, or semiconductor disk PCB parts.

FIG. 1B illustrates embodiments of printed circuit board subsystem using universal IC (UIC) chips in accordance with the present invention.

FIG. 2 shows a conventional FPGA.

FIG. 3 shows the circuit architecture applied conditions and algorithms of the invention to practice FPGA methodology.

FIG. 4 shows the device architecture and process means to support the invention circuits of both the logic and storage arrays.

FIG. 5 discloses means to program useful functional units and special net configurations.

FIG. 6 shows the flexibility of the SCL constructs for various circuit implementations.

FIG. 7 reviews the scope of USB2++ devices.

### DETAILED DESCRIPTION

The present invention relates generally to integrated circuits and more particularly to a system and method for a distributive computing subsystem. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

Mixed Signal Circuits and Process Technology for Super IC

The present invention utilizes device and system architecture for providing an intelligent nonvolatile subsystems. The nonvolatile subsystem encompasses embedded units of Flash and memory arrays (SRAM, DRAM, ROM) and programmable logic arrays. The goal is to optimize an organization of low cost, high capacity, distributive computing and memory storages. Flash transistors and SBD-CMOS transistors are the basic circuit elements to implement the various hardware constructs. SFPGA software and transmission line signal control means are keys to ensure high performance operation.

SFPGA techniques are utilized to allocate and configure certain portion of the logic circuits of a memory intensive chip. Both circuit unit types can be mixed to form a universal programmable device with Logic and Storage arrays. The users can field program certain high performance critical nets IO ports, buffers, and clocking constructs. A wide performance range switching operations can be supported. Prior art of fine-tuning clocking systems, reflection containment, data transfer protocols, and collision detection and error correction issues from leading vendors are greatly improved by the present invention.

Prior art U.S. Pat. No. 6,590,800 entitled “Schottky diode static random access memory (DSRAM) device, a method for making same, and CFET based DTL”, issued Jul. 8, 2003, by the inventor of this application describes a process and circuit scheme to lower the logic and RAM cell supply voltage to 1.2V and lower the current down to sub microampules. By lowering the current and voltage in this manner, the array peripheral organization can be revamped using low power logic circuits. Copending U.S. patent applications 3064, 3065 and 3070 also disclose these features and are incorporated by reference herein. These features therefore allow for the development of:

1. Standalone Flash memory circuits with low power peripheral logic.

2. Flash memory arrays as embedded ASIC units with other functional units on the same ship. One example of such a ship is the mix of a functional unit with low power logic gate arrays for a field reprogrammable logic gate array (FPGA) device.

A system and method in accordance with the present invention utilizes memory arrays with certain field programmable logic resources to provide circuit functionality and inter unit connectivity for the PCB. Ratios for the right mixture of the fixed and re-configurable units are at the discretion of the user as each functional part is defined.

The combined chips provide large (Gbit) storage capacity plus a large number (10-100 k) of gates, relatively smaller dedicated physical resources of processing and buffering power, re-configurable ports, and stored software constructs. Wide application chip sets can be formed from the embedded memory, processor and logic arrays in accordance with the present invention. Utilizing the system and method in accordance with the present invention, a plural number of chips can form subsystems with single to large string of super UIC chips. Finally, subsystem PCBs can provide distributive computing powers by partitioning them with various PCB arrangements and instantiated controls through reconfiguration procedures utilizing a system and method in accordance with the present invention.

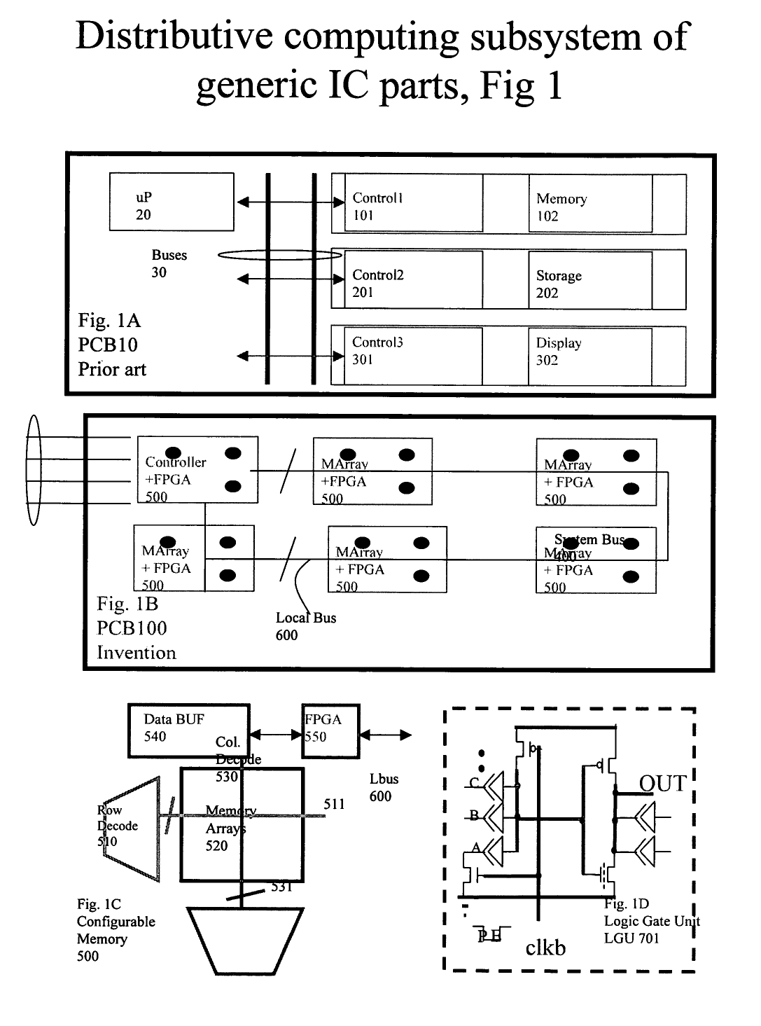

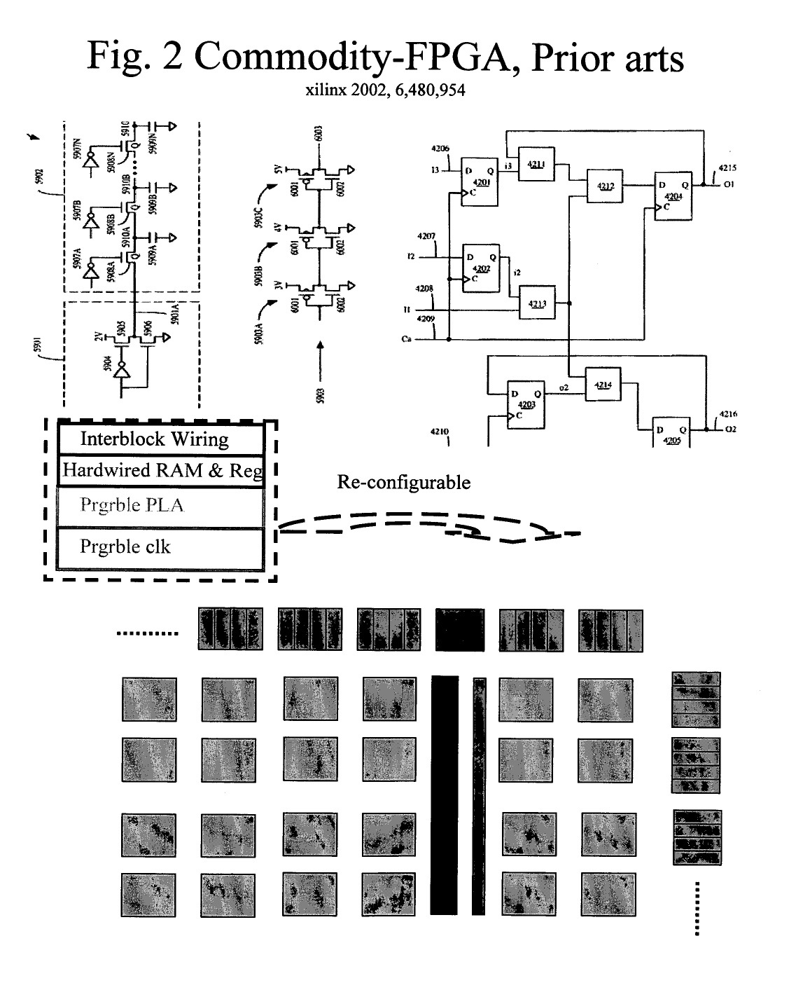

FIG. 1A shows a prior art of a host processor uP chip 20, memory module, or semiconductor disk PCB parts. Standalone IC parts are used. Usually the subsystems are formed by a ASIC controller chip(s) and standalone commodity chip, signal buffers (address regenerators, CAS, RAS controls), crystal oscillators, terminators, power regulators etc, FPGA chips, and memory chips (DRAM or MLC chips).

FIG. 1B illustrates a plurality of printed circuit board subsystems in accordance with the present invention. Chipsets are designed by semi-customed IC parts. The part utilizes SFPGA and storage arrays in accordance with the present invention. Each chipset houses certain portions of hardwired logic and storage arrays. Wiring resource and on-chip apparatus for reconfigurations are provided.

One preferred embodiment shown in FIG. 1B is the memory subsystem. The memory subsystem comprises USB (or memory as multimedia cards) semiconductor drives. Each drive PCB 100 has USB interface port 400, controller or buffer chip 700, and local bus 600 with populated memory chips 500. The USB port provides a simple low speed (10 s of Mhz) interfaces while the local bus can be high speed and high capacity. Both chip types contain pre-allocated real estate resources. Designs are supported by a UIC library, which are composed of hard and soft macro designs; IO functions, buffers, computing logics, large storage arrays and CAE software. The CAE software can include but is not limited to processing device parameters extraction, simulation modules, place and wiring programs, utilities, machine OS, reconfiguration procedures and test codes.

It is clear that much more variations can be derived by the skilled from the teachings of this invention by mixing low power SCL circuits with Flash array and FPGA for other applications at system and device levels.

In contrast to traditional PCB assembly of subsystems with ASIC controllers or microprocessors and standalone memory parts (RAM, ROM etc), a high capacity small system with ASIC chips is disclosed. These chips can be made easily with a powerful design library based on existing MLC Flash storage arrays, traditional hardwired CMOS logic gates, and the proposed SFPGA with MLC transistors. More complex embedded circuits can be composed from a school of basic functional units. Certain functional units can be field programmed by the means described later in the detailed description. Typical design entries are low power, high density, high-speed logic gates, analog units, memory units, etc. One of the embodied applications are the distributive semiconductor disk system. Another subsystems can be PCI express cards. Still another subsystem can be a networking and communication plug-in card. All are comprised of programmable intelligent processor chip(s) and information storage chip(s).

An N-type transistor disclosed in U.S. Pat. No. 6,590,800, “Schottky diode static random access memory (DSRAM) device, a method for making same, and CFET based DTL”, by the current inventor, can be utilized in the present invention. In addition to using this transistor as an information storage element, it can also be field adjusted during any configuration procedures with a dedicated on chip biasing facility. Therefore, selected logic gates or device functions (such as depletion or enhancement mode switches) can be activated, deactivated or reconfigured by the users on the fly. This flexibility greatly enhances the capacity and efficiency of a semiconductor intelligent device.

Each of the controller or memory chip contains certain portions of logic units and storage arrays. One of the preferred PCB embodiments is to enhance the presently simple logic controller chip with more code storage, error detection and correction, PLL and processing and buffer powers, so it may buffer the local commodity memory chips. Still another embodiment is to eliminate the control and signal re-powering functions of the buffer chip, but redistribute the control and repowering functions over to the presently memory commodity chips. The later system architecture creates a design paradigm forming a platform of intelligent memory chips, which support UIC with a large portion of memory intensive arrays (greater than Giga bits) but to appropriate some basic processing systems (less than 10˜100 logic gate equivalents and special IO units). Simple small systems contain single UIC chip, PC and Server systems link all plug-in PCB subsystems, each housing plural UIC chips. Therefore, computing powers are distributed over the entire system networked by the plugged PCB subsystems.

The conventional approach uses standard FPGA chips, hardwired ASIC controller chip, and Flash chips from common CMOS process foundries. The invention system architecture and methods of device integrations ensures a much higher level of system integration, superior system performance, and greater flexibility.

The goals of the system architecture are to optimize subsystem organizations for low cost and high capacity information systems using chips comprising of distributive MLC based programmable logic and memory arrays. Flash transistors, SBD-CMOS transistors, pass transistors, capacitors and resistors are the basic circuit elements to implement hardware constructs. Conventional CMOS-TTL devices with more than two way logics are compatible as is, but should be replaced for area power savings and performance improvement. FPGA programming procedural software and transmission line signal connectivity control means are keys to ensure high performance operations. The combined chips offer flexible sizes of memory and logic arrays that form arbitrary units of memory and processor powers. Plural number of chips can form distributive computing systems by various PCB arrangements and synchronized clocking controls. One cited embodiment shown in FIG. 1B is the disk sub-system. It comprises of USB semiconductor drives. Each drive PCB 100 has USB interface port 400, controller chip 700, and local bus 600 with populated memory chips 500. The USB port provides simple low speed interfaces while the local bus can be moderately high speed (hundreds of MHz) and high capacity. Both chip types are supported by a UIC library, which is composed of I/O and PLL functions, buffers, computing logics, and storage arrays.

Since all chips are memory intensive and intelligent, the universal chip can be reconfigured as a controller or as an intelligent memory chips either from the factory (more secure since one can enforce licensing controls) or allowing field alteration or modification due to any reasons. The PCB subsystems may house single or string/stack of chips with system resources added up as the PCB is augmented and more plug-ins are networked.

High Capacity MLC Logic Cell, IO Cell Constructs and Method of Programming

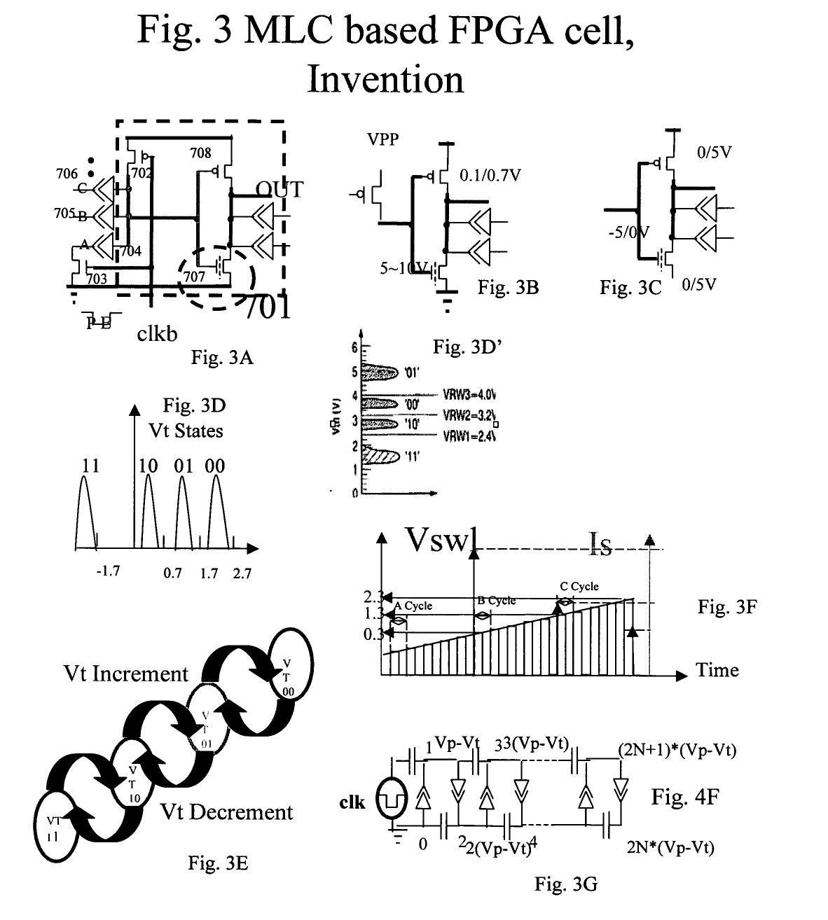

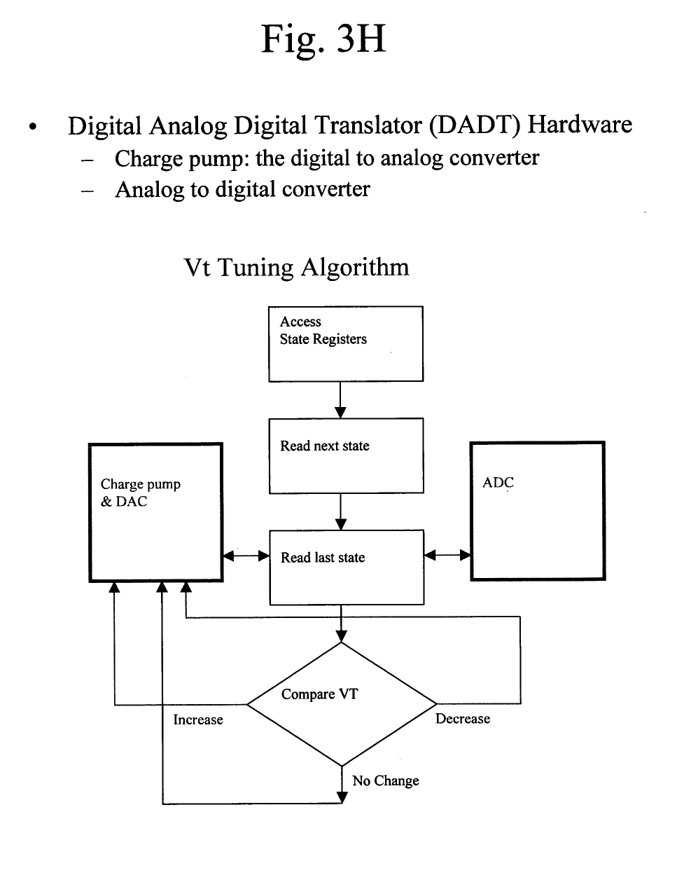

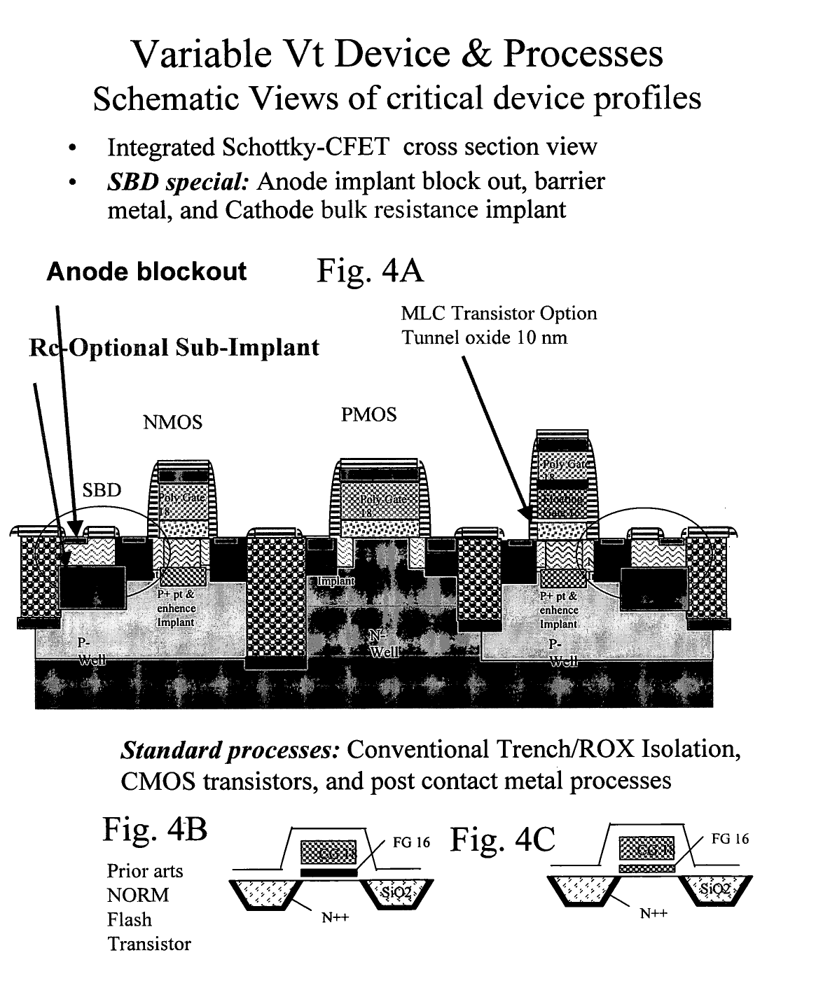

FIG. 3A shows a typical NAND gate 701 formed by field programming means. This gate comprises a signal diode tree, biasing clock (or may be called as enable) control transistor pair, and transistor inverter(s). This simple structured logic construct can be configured by software wherein reusable local and global switches and wiring tracks pre-allocated in the I/O or internal logic blocks. Conventional C++ programming procedures can be adapted and executed during the reconfiguration procedures including stacked state look up tables (LUT) that can be developed by a third party and preloaded into the storage area of the universal chip. Firstly, certain software selected switch transistors (combinations of pass transistors, MLC switches, RAM bits) are activated connecting tracks to apply conditions for the on-chip biasing and programming facility. Specific conditions are applied to carry out circuit operating conditions (FIGS. 3B and 3C) to the target switching transistor 707 (FIG. 3A) to program or adjust its conducting threshold by disposing or removal charges in its floating gate, FIG. 4A. The second phase of the reconfiguration procedure calls for connecting the intra gate wiring of metal wirings per macro functions by activating the related switches in the local logic circuit. The third phase is to complete global wirings among interface bus and IO ports of each unit. Upon completing the C++ software driven initialization cycles, all logic and IO block units are formed by wiring local and global tracks to perform their designated logic functions and interfaces.

Since the MLC transistor can be programmed with plural number of states (4) of thresholds (−1V, 0.7V, 1.7V, 2.7V in FIG. 3D and/or 1.5, 3, 3.9, 5 in FIG. 3D), it is conceivable that the gate may perform more than simple binary logic functions. However, since the diode cut in damping voltage is in the vicinity of 0.3V, one of the preferred embodiments assumes a default Vt to be 0.7V. This would yield simple binary logic gate operating with a supply voltage of 1.2V. On the other hand, if in another implementations, multiple valued Vt are allowed to be programmable, the capacity of the invented SCL circuits is greatly increased. It now serves 3 more functions: (1) binary logic inverter, (2) nonvolatile analog and digital information storage, and (3), signal comparator.

If the programming engine 400 and a DAD (digital-analog-digital) converter is closely coupled with the SCL circuit, high order (beyond ternary) logic constructs can be built with this approach.

Table 1 below summarizes the apply conditions during the reconfiguration.

TABLE 1
SFPGA Logic cell operation during POR or Re-configuration cycles

```
Programming conditions for the selected cells
    VG = 5˜10 V pulses
    Vout = 0.7 V (Vmode), or 1out = −100 uA (1mode)
    Verify Vt = 0.7 V (Default), 1.7 V, 2.7 V
Erase conditions
    VG = 0/−5 V pulses
    Vout = 5/0 V
    Verify Vt = −1 V wrt source
Advantages
    Superb RAS capability, density, speed, capacity and power attributes
        Field programmable generic logic device
    Mixed NV Logic & Memory
    Bit-wise Vt adjustment against,
        Write/Read disturbance
        Aging and leveling
```

The High Speed Transmission Line Terminator

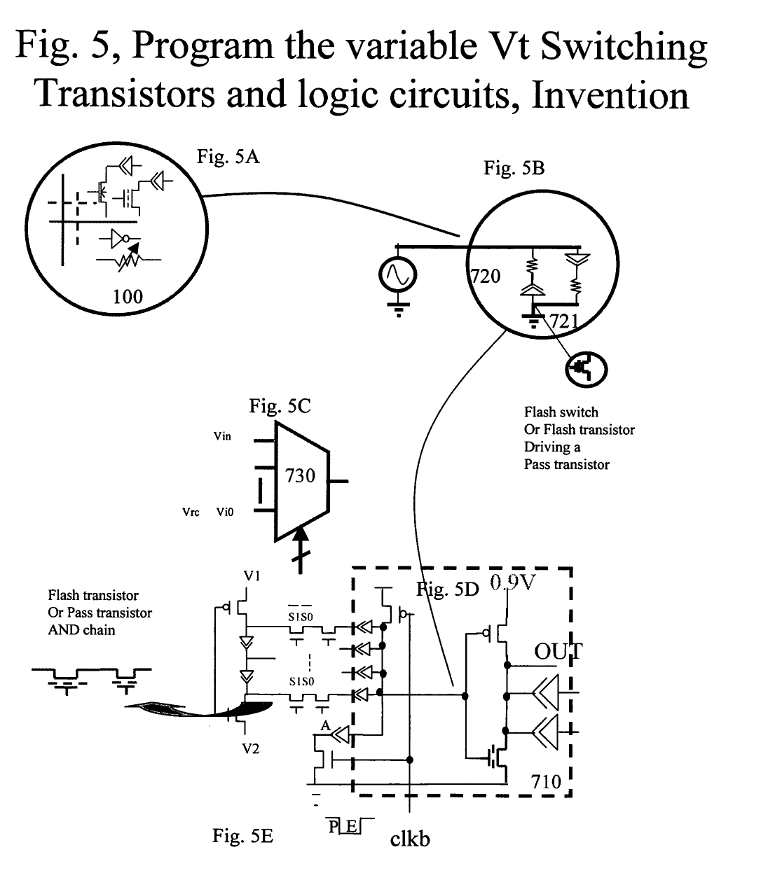

FIG. 5A shows the local on-chip resources in the programmable units of the universal IC. In FIG. 5B 721, a special termination scheme of a high-speed bus net 720 of the present invention is implemented. FIG. 5E illustrates two soft-macro circuits, MUX, FIG. 5C 730 and NAND. FIG. 5D illustrates multiplexing function and a comparator function for another SCL circuit.

In FIG. 5A, the preferred embodiment uses a MLC switch(es) to interconnect two SBD devices in the IO block to ground. With this scheme the switch may condition the net as open circuit if the apply voltage at control gate of the switch is less than stored Vt. On the other hand, it acts as an active impedance ranging from Kohm to 10 ohms subject to Vcg. Biasing. A pass transistor may also replace the single MLC transistor with its gate driven by RAM or ROM.

This switch can serve as Daisy chain terminator. When received instruction in the data protocol, it may also reconfigure a port from master driver to slave receiver for a point-to point communication, thus provides greatly flexibility and saves board spaces.

In the case of a long haul PCB transmission line, the SBD clamps may contain the overshoot or undershoots effectively for fine traces greater than 8 CM in 100 ps-class switching waveforms. The reconfiguring on-chip line termination saves PCB space, and supports well behaved point-to-point data transactions on the fly.

It is another object of the present invention to lower the voltage swing for the on-chip and off-chip switching waveforms. All circuits in SCL perform with low voltage swings, which resulted in voltage and current level scale down. The active power of nets at 1.2V is 50% less than the same circuits operating at 1.8V supply. This is particularly attractive for miniaturized systems and as laptops and handheld devices. The object is especially important where space and power savings are the main thrust in providing solutions.

The MUX and the latch are basic macro functions in forming Xlinx type FPGA devices. We introduced the MUX macro (FIG. 5C) with three embodiments shown in FIG. 5E, and 5E′ and 6A, where the desired input signal is selected by a One-Hot signal out of n choices (See Table II below).

TABLE II
SFPGA Building Blocks and MUX
Serial/parallel BUF, XOR & ECC
Reg. RAM, and MLC ROM
CLBs: SCL NOR/NAND
One Hot OHMUX or AND selector;
Truth Table, OHMUX

| Sn | S3 | S2 | S1 | S0 | Vout |
|---|---|---|---|---|---|
| 0 | 0 | 0 | 0 | 1 | C0 |
| 0 | 0 | 0 | 1 | 0 | C1 |
| 0 | 0 | 1 | 0 | 0 | C2 |
| 1 | 0 | 0 | 0 | 0 | CN |

In FIG. 5E, the multiplexing (MUX) gate is formed by a bank of pass transistors in an AND selecting scheme. The MUX can also be implemented by string of ANDed NV switches as described in FIG. 5E′. The example shown interconnects and selects multi-way reference voltage inputs to a SCL NAND gate.

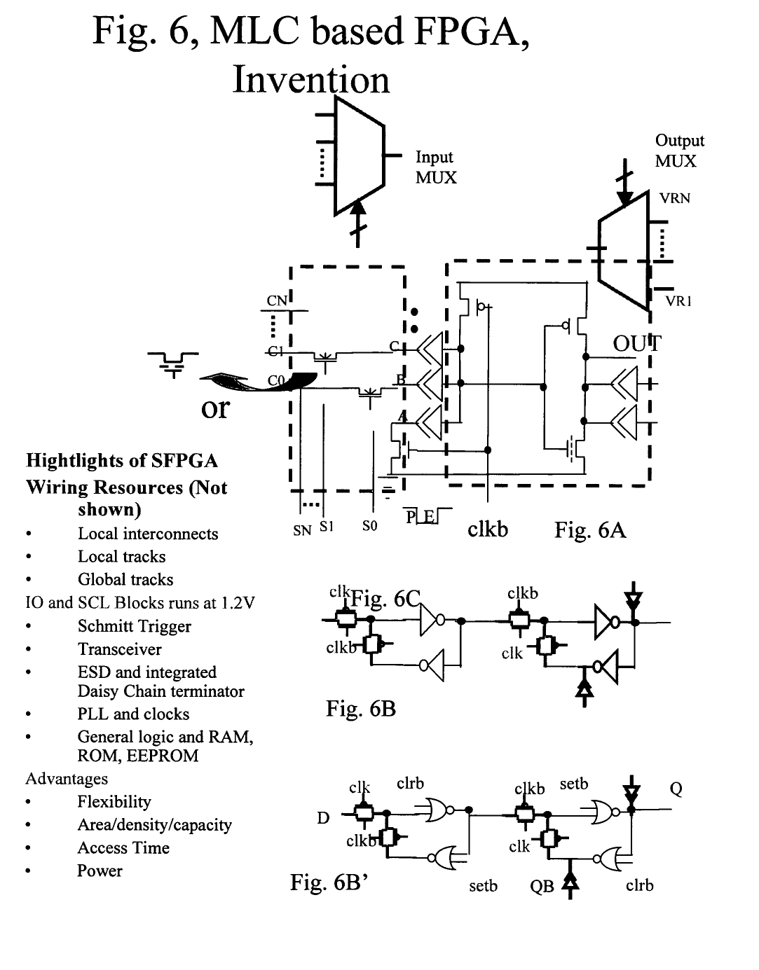

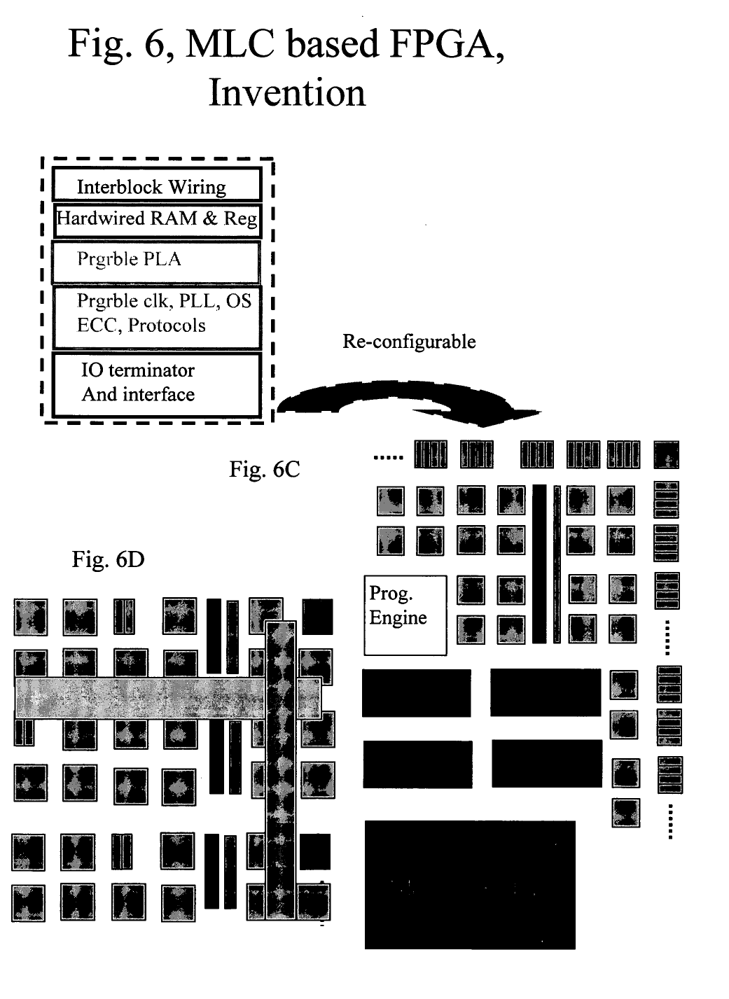

FIG. 6B and 6B′ show two schemes of Static Latch embodiments. Since the SCL is a dynamic logic implementation which does not support static logic function, the static latch becomes an essential functional unit not only to bridge SCL and CMOS-TTL circuit interface, but to hold the results statically inbetween dynamic pulses. Here, the latch serves such critical function, and all the sub-blocks requires no more than 2-way CMOS-TTL, which is acceptable as low power and low RC constant circuit implementations.

Table III below summarizes the functional merits of the SCL type MUX and Latch solutions which is efficient to support both the generic logics as well as FPGA building blocks.

TABLE III
SCL MUX and Static Latch cell attributes

```
The MUX block
    Configurable binary NOR or NAND
    Built-in level shifter
    Power-speed trade-off
    One-Hot or AND signal select MUX
    High Fan-in/out logic gates: single stage 20-way decode.
The Static Latch
    Retains results from last clock period
    Smallest power, high speed, highest density/capacity
    Provide concurrent SCL and CMOS interfaces
    Static zero power
Other Analog Functions
    ESD and Daisy Chain terminator (40 ohm GTL)
    Sense amps, RF and clipper
    Absolute value
    Power supply ladder
```

The MUX and NAND combination also forms an analog signal comparator to select signals in comparison to the stored Vt in the switching transistor 710. During the clocked evaluating window, the switch samples desired input signal to the common gate of the inverter, if its value exceeds the stored Vt, the output would switch from its otherwise dc static state.

Notice that the voltage references will provide supply derivatives either by diode drops from V1 if Vrc=0, or by diode offsets built up from V2 if Vrc=1.

The Densest Memory and Logic Technology

The preferred embodiments depicted in FIGS. 3, 5 and 6 further emphasize the goal toward memory cells and logic gates employing low power, high-speed device implementations. Briefly, a localized customization of transistor threshold of current wiring schemes are applied to portions of embedded functional units and interconnections. An emerging process known as Schottky-CMOS (SCMOS), which adopted a few process variations from conventional CMOS processes. A family of logic macro-cells is disclosed as the Schottky-CMOS-Logic (SCL). A 4T-SRAM core SBD ROM core and Flash EEPROM storage core were also disclosed. The SCMOS and its cell library offers low power memory and logic constructs that operate at 1.2V supply voltage, sub-microampere dynamic current, with pico-second performance ranges. Besides power savings, the SCL features wide NOR and NAND gating, clocked by duty cycle controlled Giga-Hertz asynchronous pulses. Each logical signal channel only takes a physical chip space of a contact size, and nearly zero capacitance loading.

Referring back to FIG. 1B, combined Flash cell and low power SCMOS logics will form an ideal solution platform for universal IC system integrations. If all the on-chip computing and storage resources are inter-operative with 1.2 V supply, the memory storage cells offered by the present invention, which targeted 4F² cell area per quadratic information storage (dual bit cell), therefore is ˜8X denser than the DRAM technology. Therefore, the EEPROM and SCMOS based gate array logic combination has the potential to house super large memory blocks (GB), distributed sub-blocks (1 Byte, nibble, and cell wise) while supporting the highest computing power from 1 k-100 k gate equivalent asynchronous compact logics with Giga-Hz clocks dissipating lowest power.

In FIGS. 3B and 3C, a generated higher biasing supply voltage when program and erasing the MLC transistors in the SCL cells and storage arrays is shown. It is the object of this invention, that all on-chip circuits be operated at lower voltages. With a 1.2 Vsupply, voltage pumps with diode and capacitors (FIG. 3) may generate up to ±5 V derivatives below and above ground. These references should be adequate to add and remove charges for the miniaturized MLC transistors. The cell Vt may then be modified by the DADT algorithm (FIG. 3H) circulating as shown in FIGS. 3E and 3F. state transition diagram. The 1.2V supply ensures that during normal circuit operations, the node voltages in each SCLs are lower enough that the float gate potential in the SCL shall not be disturbed.

It is still another objective that the SCL circuitry may implement other critical nets such as the high speed PLL or DLL paths, ring oscillators, phase detectors and splitter, multiplier. It also can support on chip serial to parallel caching, and error detection, correction for the on-chip and inter-chip data transactions.

Super PLD

A conventional PLD incorporates 6T-SRAM cells as the storage elements for reconfiguration codes and data codes. It also uses conventional CMOS-TTL logic as the building blocks for computing resources. In a system and method in accordance with the prresent invention, the PLD comprises SBD diode trees, CMOS inverters, pass transistors, and MLC transistors. Connecting paths and switches are driven by densest embedded memory arrays NAND-EEPROM cells, 4T-SRAM cells and SBD ROMs. The logic is threefore delivered by the highly area and power efficient. This super PLD will feature the most efficient field programmable devices to support the highest capacity IC solutions with ideal hardware and software capabilities.

In the preferred embodiment shown in FIG. 1B, all parts are supported by a common design library, and memory intensive Flash processes. It is assumed that the memory capacity is B cells, and logic gates are 100 k gates equivalent. The SCL based logic gate array is space economic, and operated with extremely low power.

The embedded circuit units depicted in FIGS. 1C and 1D include but are not limited to GB MLC Flash arrays 500, SRAM, ROM, hardwired CMOS-TTL, and SCL based hard gate array and FPGA. The library also contains PLL, soft-macros, C++ routines for initializations, levels of LUTs, place and route all hard macros and SCL intra-connections.

FIG. 3A shows a typical NAND unit 701. The simple circuit architecture comprises of only two closely coupled segments; an inverter and clock pulsed diode tree. The preferred embodiment employs a MLC transistor replacing NMOS switching transistor of the first stage. During the reconfiguration phase, FIG. 3B shows the inverter gate is biased at 5V while output is biased at 0.7V. This condition will program the floating gate due to exited electrons tunneling through the oxide. FIG. 3C reverses the field between the channel and control gate to remove finite charges in the local subsystem. By programming the Vt to a default value at 0.5˜0.7V range and coupling the diode logic tree to the inverter, a NAND or NOR binary logic gate is obtained. On the other hand as shown in FIGS. 3D˜3H, if we provide multi-value Vt programming scheme during determined reconfiguration cycles, more functions may be augmented or extended to the switching transistor 707 as a dual bit storage element, the SCL gate may turn into an analog and digital signal comparator, and if coupled with on-chip DADT constructs it may even carry through ternary or quaternary logic operations.

In FIG. 4, the combined device cross sectional constructs of the extended SCMOS process architecture are shown. The modified SCMOS architecture contains low barrier Schottky diodes. The floating gate electrode may use either conducting poly silicon film, or Nitride insulating film as cited in the conventional NROM process arts. The NROM device structure combined the ROX isolation with the source drain diffusion into an overlapped horizontal space, thus achieved another level of compactness. It is modified here in FIG. 4C for the floating gate material with Poly Si thin film and the structure is considered as options in our invention for the FPGA and storage arrays. This structure has the 3D proximity effect described in copending U.S. Pat. Ser. No. 10/800,257, entitled “3D Flash EEPROM Cell and the Methods of Implementing the Same,” filed on Mar. 11, 2004 and incorporated by reference in its entirety herein.. Meanwhile, the conducting floating gate guarantees the uniform and narrow Vt distributions, making it easier for lowering multi-value digitization behaviors.

FIG. 5A shows the layout 100 in a typical programmable logic element unit CLEO. The resource allocations may vary according to the circuit unit applications for IO, line driver or terminators, binary or higher logic gate, comparators, PLL and clocking, register files, latches etc. They are characterized by users and maintained in a central design library. C++ reconfiguration procedures and constructs are also stored in local MLC arrays or elsewhere in the PCB modules to guide device designs in connectivity, placement, performance estimates, and testing of the hardwired and soft wired units. FIG. 5B shows simple switch connection points for various segments of hardwired branches. There are options the simple switch may be replaced by combinations of pass transistors and NV transistor drivers or RAM array drivers. FIG. 5C-5E illustrates steps to implement complex soft macro of a comparator with reference voltage bank, a MUX, and a NAND blocks.

FIG. 6A summarizes the SCL building block and MUX constructs applicable at input and/or output nodes for SFPGA circuit reconfigurations. FIGS. 6B, and 6C illustrates the universal IC chip layout into large Analog, digital Logic, and Memory (ALM) functional organizations. There are two forms of 10 distributions; the centralized flip chip IO and the edge distributed IO. This chip architecture provides mixed signal low power IC computing solutions. The circuit and device architecture is especially efficient in space, capacity, and power-speed matrixes.

It is the main object of the present invention to implement PCB subsystems for the low power cost-performance applications. One of the product solutions is to design chip sets for field programmable version of the memory cards, stick disk drives, etc. as outlined in the Table IV below.

TABLE IV
7 USB Applications

Used by mobile devices cameras, cellular phones, PDAs, printers
CAGR 55%

| | |
|---|---|
| 1. | SmartCard |
| 2. | SmartMedia(SSFDC) |
| 3. | Compact Flash, |
| 4. | MMC |
| 5. | Secure Digital |
| 6. | Memory Stick |
| 7. | Microdrive |

Terapin host + device

| | |
|---|---|
| 1. | Canon photo printer CP-10 |
| 2. | MP3 players |
| 3. | Mini-B connectors |
| 4. | Host-PCs, Handhelds, Laptops, Cameras, Audio player, CD player, |
| | Speaker, Peripherals |

USB On-The-Go for devices serving dual roles.

Host Negotiation Protocol (HNP)
Each device has their own OS.
8 ma Vbus
Provide connection status messages: No silent Failures
Session Request Protocol tracer - SRPscreen:
Sync000000001, SOF0xA5, Frame#94, CRC50x1A, EOP250 ns,
Time3.233 us
Transaction 47:
Packet: 236, dir, reset10.000 s, idle 3.000 ms, time
stamp 00001.4993 3416

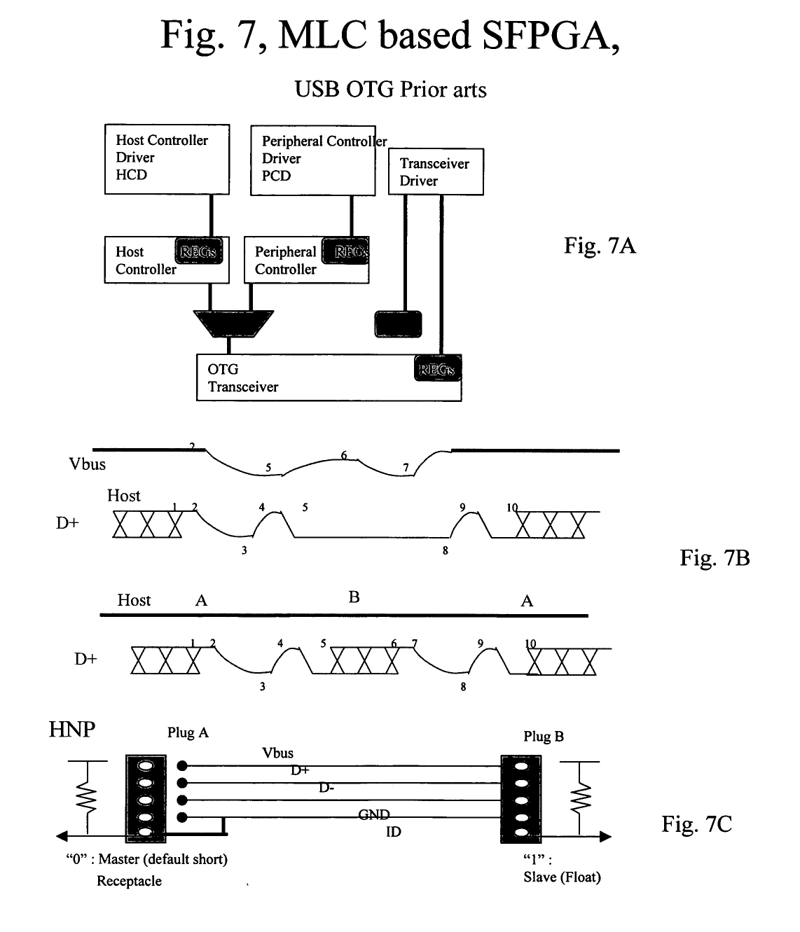

FIG. 7A is the functional block diagram of a typical USB interface units. There are host and peripheral controllers, transceivers. The system bus data transactions support 480 MHz serial data processing and low speed handshakes. USB on-the-go (OTG) add a master/slave mode identification pin for point to point data transmission. The master slave port identification is et by Table V below.

TABLE V
USB Target Applications

| Master | Slave | Application |
|---|---|---|
| Mobile Phone | Mobile Phone | Exchange contact Info. |
| | Still image | Email pictures |
| | MP3 Player | Upload Pic to Web |
| | Mass storage | Up/Down load/Broadcast music |
| | Scanner | Up/Down Load files |
| | | Scan Business cards |
| Still Image | Still Image Camera | Exchange pictures |
| Camera | Mobile phone | email Pictures |
| | Printer | Upload Pic to Web |
| | Mass storage | Print/store pictures |
| Printer | Still Image Camera | Print/store pictures |
| | Scanner | Print/storescanned pictures |
| MP3 Player | MP3 Player | Exchange Songs |
| | Mass storage | Up/Down load songs |
| Oscilloscope | Printer | Print screen image |
| PDA | PDA | Exchange files |
| | Printer | Print files |
| | Mobile phone | Up/Down Load files |
| | MP3 Player | Up/Down Load songs |
| | Scanner | Scan pictures |
| | Mass storage | Obtain Directions |
| | GPS | Mapping info. |
| | Still Image Camera | Upload pictures |
| | Oscilloscope | Configure Oscilliscope |

With the scheme provided by the present invention, the local OS may assign the mode of each ports according to information received from preceding frames. The master slave ports, and driver or net terminators are identified and reconfigured prior to each local data transfers. The system OS will maintain certain coherences according to agreed protocols. For small or large systems, each of the PCB subsystem may be implemented with a single chip or string of universal chips (8˜32). Local bus nets within the PCB subassembly may run at comfortable lower speed (say BW=400 MB with 16 bit bus width at 200 MHhz). With prior arts in PLL and frequency multiplier schemes, higher speed nets (BW=4 GB with 16 bit bus, dual phase clock at 1 Ghz) are possible to parallel process signals within each chips distributed over the entire distributive subassemblies.

The chip sets may support all memory intensive but intelligent systems. Each subsystem has independent computing power with GB storage and 10 s˜100K logic gate equivalent and analog signal processing power, simple system bus (4 digital pins and a couple of Op Amp pins) and high speed local bus interface capabilities. FPGA facility is provided for customizing special local nets so global synchronization and parallel processing is possible. A great flexibility is built-in with each subsystem such that additive computing power is distributed over the entire network with privileged clients.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A printed circuit board (PCB) data processing and storage subsystem comprising:
a signal bus;
a multilevel cell (MLC) Flash Array; and
a field programmable gate array (FPGA), the FPGA including a MLC transistor, wherein the subsystem provides a low power, high performance dense and high capacity distributive semiconductor system.

2. The PCB subsystem of claim 1 is includes a multi-layer printed circuit board housing with integrated chips, each of the integrated chips performing analog, logic and a memory functions.

3. The PCB subsystem of claim 1 is provided with several levels of signal bussing schemes; simple system bus low speed (˜10 s MHz) connections, medium speed (100 MHz) inter chip bus wirings, and super speed (GHz) on-chip bus nets.

4. The PCB subsystem of claim 1 comprises standalone functional chips.

5. The PCB subsystem of claim 1 comprises embedded mixed functional chips.

6. The PCB subsystem of claim 1 which includes conventional CMOS transistors, Flash transistors, Schottky barrier diodes, capacitors, resistors, and wiring tracks among other circuit elements and resources on the PCB subsystem.

7. The PCB subsystem of claim 1 includes any of the following integrated circuits: conventional and customized CMOS-TTL circuits, embedded memory (RAM and EEPROM) arrays, embedded PLL and clock multiplication circuits, embedded ECC circuits, Schottky ROM arrays, hardwired Schottky CMOS logic (SCL) gate arrays, and soft wired Schottky Filed Programmable Gate Arrays (SFPGA).

8. The PCB subsystem of claim 7 wherein the subsystem includes conventional software driven CMOS-TTL FPGA devices and hardware constructs of mixed SCL circuits.

9. The PCB subsystem of claim 8 wherein the SCL circuit may incorporate a Flash transistor.

10. The PCB subsystem of claim 9 wherein the Flash transistor acts as a switching transistor for the binary logic gate.

11. The PCB subsystem of claim 9 wherein the Flash transistor acts as an individual circuit element, which stores multi-value analog (4 level of Vt) and digital information (more than 2 bits per cell).

12. The PCB subsystem of claim 9 wherein the Flash transistor may be used as a switch, which exhibits variable resistances.

13. The PCB subsystem of claim 9 wherein the Flash transistor may be used as a switch to drive a pass transistor(s), which interconnect and select signals, wiring tracks, or provide on-chip for off-chip transmission line terminations.

14. The PCB subsystem of claim 9 wherein the flash and pass transistor combinations may form a MUX functional construct to apply biasing voltage or current condition during reconfiguration processes.

15. The PCB subsystem of claim 9 wherein the SCL circuit may be configured to perform analog and digital comparator functions

16. The PCB subsystem of claim 9 wherein the SCL circuit may be configured to perform analog-to-digital converter function.

17. The PCB subsystem of claim 9 wherein the SCL circuit may be configured to perform digital-to-analog comparator functions.

18. The PCB subsystem of claim 8 wherein the software to guide the reconfiguration processes is residing in the storage array

19. The PCB subsystem of claim 1 wherein the on-chip software may further include but not limited to protocols, algorithms, test routines, OS cores.
